(19) United States
(12) Patent Application Publication
(10) Pub. No.: US 2025/0266278 A1
(43) Pub. Date: Aug. 21, 2025

(54) SUBSTRATE HOLDING DEVICE, SUBSTRATE PROCESSING APPARATUS AND SUBSTRATE HOLDING METHOD

(71) Applicant: SCREEN Holdings Co., Ltd., Kyoto (JP)

(72) Inventor: Takanori HIRAI, Kyoto-shi (JP)

(21) Appl. No.: 19/002,393

(22) Filed: Dec. 26, 2024

(30) Foreign Application Priority Data
Feb. 21, 2024 (JP) 2024-024277

(51) Int. Cl. H01L 21/68; H01L 21/67; H01L 21/683

(52) U.S. Cl. CPC H01L 21/68; H01L 21/67023; H01L 21/6838

(57) ABSTRACT

A substrate holding device includes: a mounting table having a mounting surface on which a substrate is to be mounted; an up-down unit configured to mount the substrate on the mounting surface by moving down a plurality of support pins supporting the substrate from below; a suction unit configured to suck and hold a peripheral part of the substrate from below using a suction pad; a positioning unit configured to position the substrate by abutting on an end surface of the substrate supported by the plurality of support pins at a positioning position separated upward from the suction pad; and a controller configured to control the up-down unit, the suction unit, the up-down unit and the positioning unit. The substrate positioned by the positioning unit is mounted on the mounting surface and then held in suction by the suction unit.

### CROSS REFERENCE TO RELATED APPLICATION

The disclosure of Japanese Patent Application No. 2024-24277 filed on Feb. 21, 2024 including specification, drawings and claims is incorporated herein by reference in its entirety.

### BACKGROUND OF THE INVENTION

### 1. Field of the Invention

The present invention relates to a substrate holding technique of holding substrates on mounting tables that are glass substrates for FPDs such as liquid crystal display devices or organic EL display devices, semiconductor wafers, glass substrates for photomasks, substrates for color filters, substrates for recording disks, substrates for solar cells, substrates for precision electronic devices such as substrates for electronic paper, and substrates for semiconductor packages (these substrates will hereinafter be called “substrates” simply), and a substrate processing technique of applying processing liquids to the substrates held on the mounting tables by supplying the processing liquids from slit nozzles.

### 2. Description of the Related Art

Known examples of a substrate processing apparatus include a coating device that applies a processing liquid to a substrate by ejecting the processing liquid to the substrate from a slit nozzle having a slit-like ejection opening while moving the slit nozzle relative to the substrate. As an example, Japanese Patent Application Laid-Open No. 2013-192980 shows an apparatus that applies a processing liquid to a substrate while moving a slit nozzle above a stage surface (corresponding to an example of a “mounting surface” of the present invention) of a stage with the substrate kept held on the stage surface. This apparatus includes a suction cup (corresponding to an example of a “suction pad” of the present invention) provided in the vicinity of a surface of the stage and used for holding a lower surface of a corner of the substrate under suction. The suction cup is connected to an exhaust unit such as a vacuum pump or an exhaust fan. Thus, by exhausting air via the suction cup, the lower surface of the corner of the substrate is held under suction by the suction cup. Then, the processing liquid ejected from the slit nozzle is applied to the substrate held under suction by the suction cup.

### SUMMARY OF INVENTION

A position for mounting the substrate on the stage surface is set in advance. Deviation of the substrate from the mounting position results in the failure to apply the processing liquid favorably. In response to this, incorporating a unit such as a positioning unit or a position adjusting mechanism into the substrate processing apparatus has been suggested. This unit is to adjust the position of the substrate before the substrate is held under suction by the suction cup. As an example, the invention shown in Japanese Patent Application Laid-Open No. 2017-112197 is available as the unit including the positioning unit. The position adjusting mechanism shown therein has a plurality of alignment pins. These alignment pins are provided in such a manner as to surround a substrate supported from below by a suction cup. Each of the alignment pins is horizontally movable toward the substrate. When the alignment pins move toward the substrate and abut on a peripheral edge of the substrate, the substrate is located in a position set in advance (alignment process).

Simply combining the invention shown in Japanese Patent Application Laid-Open No. 2013-192980 and the invention shown in Japanese Patent Application Laid-Open No. 2017-112197 described above causes a problem as follows. During the positioning process described above, each suction cup is in contact with the substrate. Hence, the substrate rubs against the suction cup when the substrate is moved horizontally by the alignment pins. This horizontal movement causes dust generation from the suction cup and wear of the suction cup, leading to quality reduction in the substrate process.

The present invention has been made in view of the foregoing problem. In a substrate holding device and a substrate processing apparatus using the substrate holding device that hold a substrate under suction on a mounting table using a suction pad while the substrate is located in a predetermined position relative to the mounting table, the present invention is intended to prevent generation of dust from the suction pad and wear of the suction pad.

A first aspect of the invention is a substrate holding device. The device comprises: a mounting table having a mounting surface on which a substrate is to be mounted; an up-down unit configured to mount the substrate on the mounting surface by moving down a plurality of support pins supporting the substrate from below; a suction unit configured to suck and hold a peripheral part of the substrate from below using a suction pad; a positioning unit configured to position the substrate by abutting on an end surface of the substrate supported by the plurality of support pins at a positioning position separated upward from the suction pad; and a controller configured to control the up-down unit, the suction unit, and the positioning unit so as to cause the up-down unit to mount the substrate on the mounting surface and to cause the suction unit to hold the substrate under suction while the substrate is positioned by the positioning unit.

A second aspect of the invention is a substrate processing apparatus. The apparatus comprises: the substrate holding device; and a slit nozzle configured to apply a processing liquid to a surface of the substrate by moving relative to the substrate in a horizontal direction while the substrate is mounted on the mounting surface and is held under suction on the mounting table by the suction pad.

A third aspect of the invention is a substrate holding method. The method comprises: (a) sucking and holding a substrate on a mounting surface of a mounting table using a suction pad of a suction unit; (b) after the operation (a), positioning the substrate above the mounting surface and the suction pad by causing a positioning member to abut on an end surface of the substrate while supporting the substrate from below using a plurality of support pins; and (c) after the operation (b), mounting the substrate on the mounting surface by moving down the plurality of support pins.

According to the invention having the foregoing configuration, while the substrate is supported from below by the plurality of support pins in the positioning position separated upward from the suction pad, the positioning member abuts on the end surface of the substrate. By doing so, the substrate is positioned in the horizontal direction. During implementation of this positioning process, the substrate is moved in the horizontal direction while the substrate is a posture of not abutting on the suction pad. After being subjected to the positioning process, the substrate is mounted on the mounting surface by the up-down unit and is held under suction by the suction unit.

As described above, according to the present invention, while generation of dust from the suction pad and wear of the suction pad are prevented, it is possible to hold the substrate under suction on the mounting table using the suction pad with the substrate located in a predetermined position relative to the mounting table.

All of a plurality of constituent elements of each aspect of the present invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the present invention described above can be combined with some or all of technical features included in another aspect of the present invention described above to obtain one independent form of the present invention in order to solve some or all of the aforementioned problems or to achieve some or all of the effects described in this specification.

### BRIEF DESCRIPTION OF THE DRAWINGS

FIG. 1 schematically shows an entire configuration of a coating device corresponding to an embodiment of a substrate processing apparatus according to the present invention.

FIG. 2 is a plan view of a principal part of the substrate holding mechanism viewed from above.

FIG. 3 schematically shows the configuration of the substrate holding mechanism.

FIG. 4 is a flowchart showing an example of a substrate holding process performed by the substrate processing apparatus in FIG. 1.

FIG. 5 is a flowchart showing a procedure of temporary correction on the substrate taken by the substrate holding mechanism in FIG. 2.

FIGS. 6A and 6C to 6E are motion explanatory views showing motions conducted according to the flowchart in FIG. 4.

FIG. 6B is a motion explanatory view showing a motion conducted according to the flowchart in FIG. 5.

### DETAILED DESCRIPTION OF THE PREFERRED EMBODIMENTS

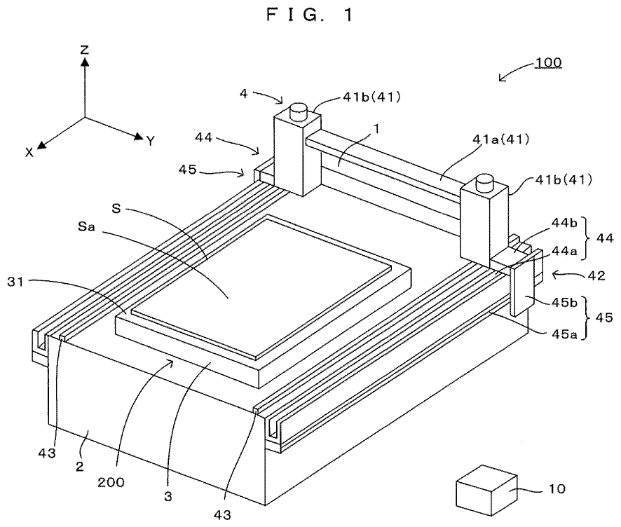

FIG. 1 schematically shows an entire configuration of a coating device corresponding to an embodiment of a substrate processing apparatus according to the present invention. In FIG. 1 and each of the subsequent drawings, to clearly show a relationship in terms of direction between the drawings, an XYZ orthogonal coordinate system is given in appropriate cases where a vertical direction is represented as a Z direction and a horizontal plane is represented as an XY plane. In the drawings, the dimension of each part or the number of suck parts is drawn in an exaggerated or simplified manner, as necessary.

A substrate processing apparatus 100 includes a substrate holding mechanism 200 corresponding to an example of a “substrate holding device” according to the present invention. A controller 10 controls each part of the substrate processing apparatus 100. As a result, while a substrate S is held by the substrate holding mechanism 200, a slit nozzle 1 moves in the X direction relative to the substrate S to apply a processing liquid to a surface Sa of the substrate S. Specifically, the substrate processing apparatus 100 is an apparatus called a slit coater. Photoresist liquids, pigments for color filters, polyimide precursors, silicon agents, nanometal inks, or various types of paste or slurry processing liquids containing conductive materials are available as the processing liquid, for example. The substrate S is a glass substrate having a rectangular shape in a plan view. The substrate S as a coating target is applicable to various types of substrates such as rectangular glass substrates, semiconductor substrates, flexible substrates for film liquid crystal, substrates for photomasks, substrates for color filters, substrates for solar cells, substrates for organic electroluminescence (EL), and substrates for semiconductor packages. In the present specification, of both main surfaces of the substrate S, “the surface Sa of the substrate S” means a main surface to be coated with the processing liquid.

In the substrate processing apparatus 100, a stage 3 corresponding to one of constituting elements of the substrate holding mechanism 200 is arranged on a base 2. The substrate S is to be mounted on an upper surface of the stage 3 (hereinafter called a “mounting surface 31”) and is to be held under suction thereon. The configuration and motion of the substrate holding mechanism 200 will be described later in detail.

The slit nozzle 1 is arranged above the stage 3. The slit nozzle 1 has a slit-like ejection opening extending in the Y direction, and is capable of ejecting the processing liquid from the ejection opening toward the surface Sa of the substrate S held on the stage 3. The substrate processing apparatus 100 is provided with a nozzle moving unit 4 that moves the slit nozzle 1 back and forth in the X direction above the stage 3. The nozzle moving unit 4 includes a nozzle support 41 having a bridge structure extending transversely in the Y direction above the stage 3 to support the slit nozzle 1, and a nozzle drive mechanism 42 that moves the nozzle support 41 horizontally in the X direction.

The nozzle support 41 includes a fixing member 41a to which the slit nozzle 1 is fixed, and two up-down units 41b that move the fixing member 41a up and down while supporting the fixing member 41a. The fixing member 41a is a rod-like member extending lengthwise in the Y direction and having a rectangular sectional shape, and is made of a material such as carbon fiber reinforced resin. The two up-down units 41b are coupled to opposite end portions of the fixing member 41a in the lengthwise direction, and have respective AC servo motors, ball screws, etc. The up-down units 41b move the fixing member 41a and the slit nozzle 1 integrally up and down in the vertical direction (Z direction) to adjust an interval between the ejection opening of the slit nozzle 1 and the substrate S, namely, the height of the ejection opening relative to an upper surface of substrate S.

The nozzle drive mechanism 42 includes two guide rails 43 along which the movement of the slit nozzle 1 is guided in the X direction, two linear motors 44 as drive sources, and two linear encoders 45 for detecting the position of the ejection opening of the slit nozzle 1. The two guide rails 43 are arranged at opposite ends of the base 2 in the Y direction in such a manner as to interpose the stage 3 therebetween in the Y direction, and are extended in the X direction in such a manner as to cover the stage 3. Respective lower end portions of the two up-down units 41b are guided along the corresponding two guide rails 43, thereby moving the slit nozzle 1 in the X direction above the substrate S held on the stage 3.

Each of the two linear motors 44 is an AC coreless linear motor having a stator 44a and a mover 44b. The stator 44a is arranged at each of side surfaces of the base 2 in the Y direction in such a manner as to extend in the X direction. The mover 44b is fixed externally to the up-down unit 41b. The linear motor 44 functions as a drive source of the nozzle drive mechanism 42 using magnetic force generated between the stator 44a and mover 44b.

Each of the two linear encoders 45 has a scaling part 45a and a detector 45b. The scaling part 45a is provided at the bottom of the stator 44a of the linear motor 44 fixed to the base 2, and is extended in the X direction. The detector 45b is fixed still externally to the mover 44b of the linear motor 44 fixed to the up-down unit 41b, and is arranged face-to-face with the scaling part 45a. The linear encoder 45 detects the position of the ejection opening of the slit nozzle 1 in the X direction on the basis of the positions of the scaling part 45a and the detector 45b relative to each other. Specifically, in the present embodiment, while the up-down unit 41b adjusts an interval between the slit nozzle 1 and the substrate S in the Z direction, the nozzle drive mechanism 42 moves the slit nozzle 1 in the X direction relative to the substrate S. During this relative movement, the processing liquid is ejected from the slit nozzle 1 to supply the processing liquid to the upper surface of the substrate S (a coating process of applying the processing liquid).

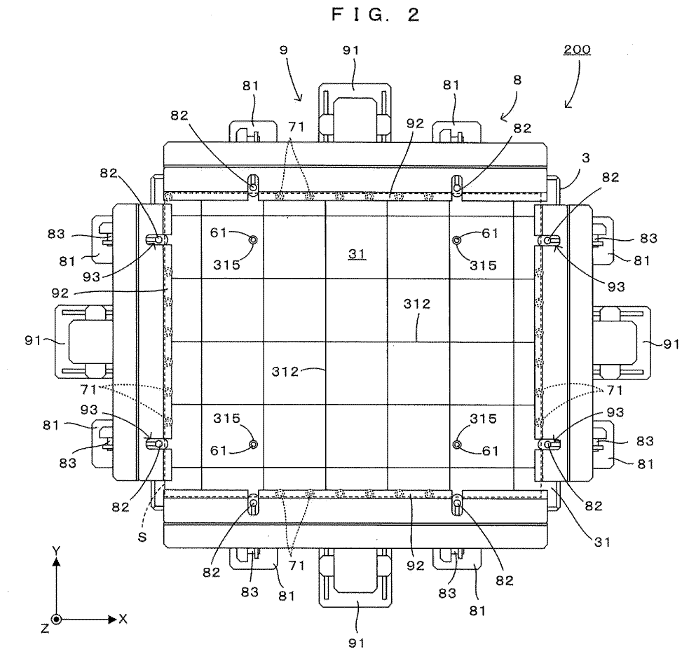

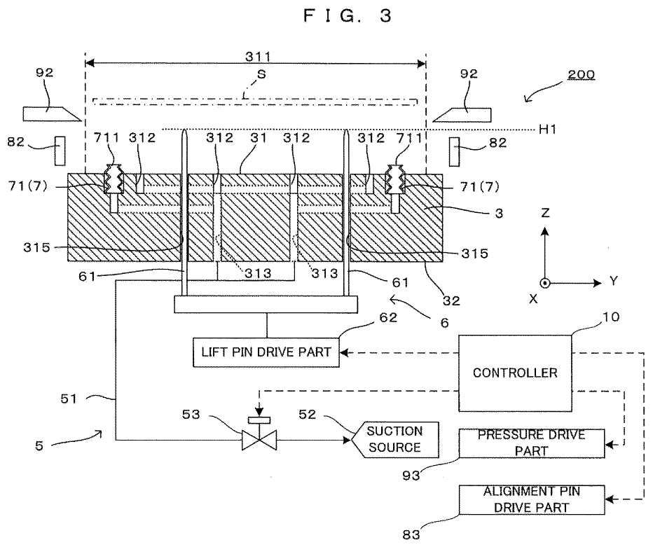

FIG. 2 is a plan view of a principal part of the substrate holding mechanism viewed from above. FIG. 3 schematically shows the configuration of the substrate holding mechanism. The configuration and motion of the substrate holding mechanism 200 will be described by referring to these drawings.

In the substrate holding mechanism 200, the stage 3 corresponds to an example of a “mounting table” of the present invention. The stage 3 used herein is a stone surface plate providing the mounting surface 31 with flatness of about several micrometers, for example. The mounting surface 31 has a central part functioning as a substrate mounting region 311 allowing the substrate S to be mounted therein. The substrate mounting region 311 has a central part where suction grooves 312 are formed in a grid pattern in response to an effective area of the substrate S, and a peripheral part with a plurality of suction pads 71 provided in such a manner as to surround the suction grooves 312.

The effective area of the substrate S means a region for providing a plurality of elements in a central part of the upper surface of the substrate S. In the case of a semiconductor package, for example, a rectangular glass substrate corresponds to the substrate S, and a plurality of semiconductor chips, interconnect lines between the chips, and others stacked in a central part of an upper surface of the glass substrate correspond to the plurality of elements. When the substrate S is mounted in the substrate mounting region 311, the effective area becomes located over the central part of the substrate mounting region 311. As shown in FIG. 2, in the central part of the substrate mounting region 311, the suction grooves 312 are formed in a grid pattern in order to hold the effective area of the substrate S firmly under suction on the mounting surface 31. Specifically, the grooves are extended in the X direction and the Y direction to a certain depth from the mounting surface 31, and at some intersecting points where the grooves intersect each other, through holes 313 extending in the Z direction are formed that lead to a lower surface 32 of the stage 3 from the corresponding intersecting points.

As shown in FIG. 3, each of the through holes 313 is connected to a negative pressure generator 5. The negative pressure generator 5 includes a suction pipe 51, a suction source 52, and an on/off valve 53. More specifically, the suction source 52 is connected to the through hole 313 via the suction pipe 51. The suction source 52 to be used may be a vacuum pump or resources in a factory where the substrate processing apparatus 100 is installed, for example. The on/off valve 53 is interposed in the suction pipe 51. In response to a closing command from the controller 10, the on/off valve 53 is closed to stop supply of a negative pressure to the through hole 313. In response to an opening command from the controller 10, the on/off valve 53 is opened to supply a negative pressure to the through hole 313. Specifically, when the on/off valve 53 is opened in response to the opening command from the controller 10 after mounting of the substrate S in the substrate mounting region 311, a negative pressure is supplied to the through hole 313, as will be described later. By doing so, air is exhausted from space sandwiched between a lower surface of the effective area of the substrate S and the mounting surface 31 via the suction groove 312 and the through hole 313, thereby holding the substrate S under suction on the mounting surface 31.

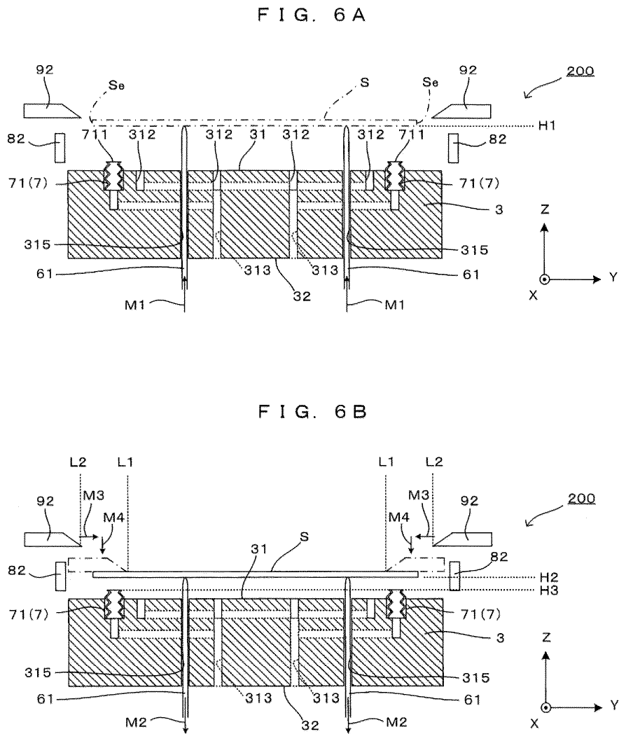

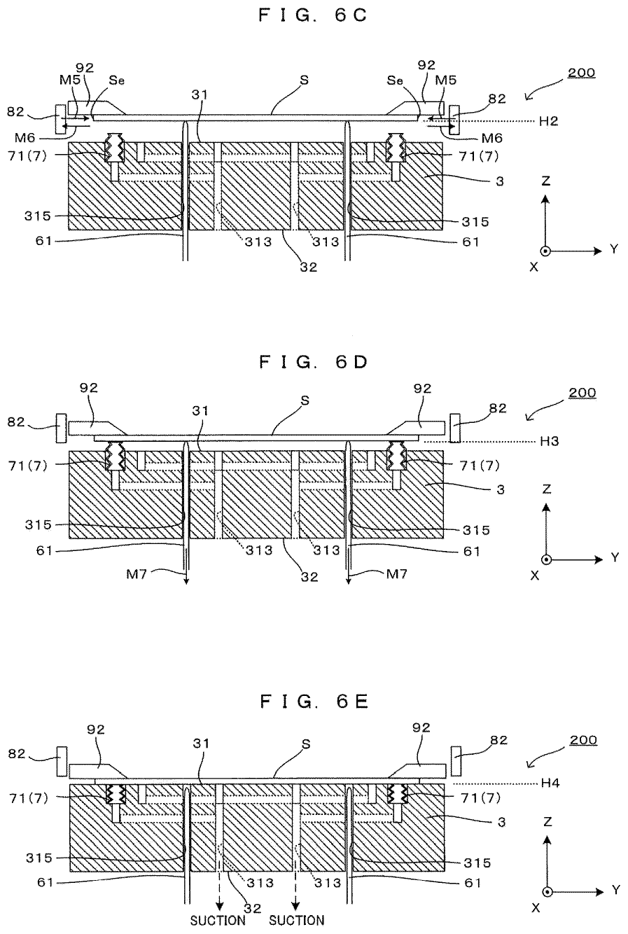

In this way, the effective area of the substrate S is held under suction by the negative pressure generator 5. Meanwhile, a region external to the effective area, namely, a non-effective area is located over the peripheral part of the substrate mounting region 311. Hence, on the occurrence of warpage in the non-effective area, air goes into exhaust target space (between the effective area and the stage 3) from the warped portion to cause reduction in suction force. Then, in the present embodiment, in the peripheral part of the substrate mounting region 311, a plurality of recesses is provided in the mounting surface 31 in such a manner as to surround the suction grooves 312 in a grid pattern, and the suction pad 71 is provided in each of the recesses. As shown in FIG. 3, the suction pad 71 has a suction upper end portion provided with a suction opening 711 for sucking a lower surface of the substrate S, and a suction lower end portion sunk in the recess. Like the suction groove 312, the suction lower end portion is connected to the negative pressure generator 5. Thus, in response to a closing command from the controller 10, the on/off valve 53 is closed to stop supply of a negative pressure to the suction pad 71. At this time, the suction upper end portion of the suction pad 71 protrudes to be higher by about 1 mm than the mounting surface 31 and is capable of supporting a peripheral part of the substrate S from below kept in a non-sucked state. The height position of the suction opening 711 determined at this time (sign H3 in FIG. 6B described later) corresponds to an example of a “pad abutment position” of the present invention. Meanwhile, in response to an opening command from the controller 10, the on/off valve 53 is opened to supply a negative pressure to the suction pad 71. By doing so, suction of the substrate S is started.

The suction pad 71 has a so-called bellows shape and is expandable and contractible in the vertical direction Z. Thus, after the lower surface of the substrate S comes into abutting contact with the suction opening 711 of the suction pad 71, namely, after formation of an abutment state, the suction upper end portion of the suction pad 71 retreats into the recess while keeping abutting contact with the substrate S in conjunction with downward movement of the substrate S caused by an up-down unit 6 described later to become sinkable in the recess at a moment when mounting of the substrate S on the mounting surface 31 is finished. As described, in the present embodiment, a suction unit 7 is composed of the plurality of suction pads 71, and sucks and holds the peripheral part of the substrate S from below.

In the present embodiment, in response to opening and closing of the on/off valve 53, a switch between sucking the substrate and stopping the suction using the suction groove 312 and a switch between sucking the substrate and stopping the suction using the suction pad 71 are made simultaneously. Meanwhile, in one configuration, these switches may be made independently of each other by providing an on/off valve dedicated to the suction groove and an on/off valve dedicated to the suction pad.

The up-down unit 6 has a plurality of lift pins 61 and a lift pin drive part 62. The stage 3 is provided with a plurality of pin housing holes 315 extended parallel to the Z direction and opened at the mounting surface 31, and the lift pins 61 are housed in the corresponding pin housing holes 315. In the present embodiment, four pin housing holes 315 are provided and the substrate S is configured to be moved up and down by the four lift pins 61. However, the number of the lift pins 61 is not limited to “4” but may be changed as appropriate in response to a planar size or weight of the substrate S, for example.

Each lift pin 61 is configured by attaching a head cap made of a resin material removably to a head of a lift pin body made of metal such as stainless steel, for example, and has a pin shape extended parallel to the Z direction as a whole. As the resin material forming the head cap, polyether ether ketone (PEEK) or ultra-high molecular weight polyethylene (UPE) is available, for example. A head portion, namely, the head cap of each lift pin 61 comes into contact with the lower surface of the substrate S as described next and is worn in response to an increased frequency of the contact. Thus, as the wear develops further, the head cap is changed regularly by an operator.

When the controller 10 for controlling the apparatus entirely gives an up-down command to the lift pin drive part 62, the lift pin 61 is moved up and down. By doing so, the lift pin 61 moves forward and backward relative to the pin housing hole 315. As shown in FIG. 3, moving the lift pin 61 up until the head of the lift pin 61 reaches a height position H1 allows the substrate S to be transferred to and from a robot not shown in the drawings. Namely, the height position H1 corresponds to an example of a transfer position for the substrate S. When the substrate S having been transported by the robot reaches a position over the stage 3, the lift pins 61 are driven by the lift pin drive part 62 to move up, thereby protruding from the pin housing holes 315 to become higher than the mounting surface 31. Then, the respective upper ends of the lift pins 61 come into point contact with the lower surface of the substrate S and receive the substrate S. Next, the lift pins 61 are driven by the lift pin drive part 62 to move down to be housed into the pin housing holes 315. By doing so, the substrate S is mounted in the substrate mounting region 311 from the upper ends of the lift pins 61. In lifting the substrate S from the substrate mounting region 311, the lift pins 61 are driven by the lift pin drive part 62 to move up, thereby protruding from the pin housing holes 315 to become higher than the mounting surface 31.

In the present embodiment, a positioning position (sign H2 in FIG. 6B) is set between the transfer position (sign H1 in FIGS. 3 and 6A) and the pad abutment position (sign H3 in FIG. 6B) in the vertical direction Z. The positioning position is set in order to position the substrate S in a horizontal direction received from the robot and before being subjected to the coating process using a positioning unit 8 while avoiding sliding contact with the suction pad 71 (position adjusting process). Furthermore, in the present embodiment, a pressure unit 9 is provided for performing a warpage correcting process of correcting a warpage of the substrate S simultaneously with or before or after implementation of the position adjusting process.

In the present embodiment, the positioning unit 8 and the pressure unit 9 are provided by employing configurations similar to the position adjusting mechanism and the pressure mechanism shown in Japanese Patent Application Laid-Open No. 2017-112197. Thus, in the following, detailed descriptions of the configurations of the positioning unit 8 and the pressure unit 9 will be omitted and the configurations of these units will be described briefly by referring to FIGS. 2 and 3.

The positioning unit 8 includes eight position adjusters 81 in total arranged two by two along each side of the mounting surface 31. Each of the position adjusters 81 includes a pin-shape alignment pin 82 extended parallel to the Z direction. Specifically, the two alignment pins 82 are arranged separately from each other in the horizontal direction along each side surface of the stage 3. The alignment pin 82 is arranged higher than the mounting surface 31 in such a manner as to be horizontally movable between space over the stage 3 and separated space separated from the over space toward an external side of the stage. More specifically, as shown in FIG. 3, a lower end of the alignment pin 82 is located in a position higher than the mounting surface 31 and lower than the pad abutment position (sign H3 in FIG. 6B). Meanwhile, an upper end of the alignment pin 82 is located in a position higher than the positioning position (sign H2 in FIG. 6B) and lower than the transfer position (sign H1 in FIGS. 3 and 6A). Thus, with the substrate S located in the positioning position, the alignment pin 82 faces an end surface Se of the substrate S in the horizontal direction.

An alignment pin drive part 83 is connected to the alignment pin 82 having the foregoing configuration. When the alignment pin drive part 83 is actuated in response to a positioning command from the controller 10, the alignment pin 82 at a retreat position moves horizontally toward the substrate S in the positioning position to abut on the end surface Se of the substrate S. By doing so, the substrate S is located in a predetermined position in the horizontal direction (position adjusting process or may also be called an alignment process). When the controller 10 gives a retreat command to the alignment pin drive part 83 after implementation of the position adjusting process, the alignment pin 82 moves farther from the substrate S to return to the retreat position.

The pressure unit 9 includes four pressure parts 91 in total arranged one by one along each side of the mounting surface 31. Each of the pressure parts 91 includes a pressure member 92 extended along a corresponding side of the mounting surface 31. Each pressure member 92 is provided movably between a standby position, a temporary correction position, and a final correction position. The standby position means the position of the pressure member 92 during loading and unloading of the substrate S, during a period waiting for loading of the substrate S, and during implementation of the coating process. As shown in FIG. 3, when the pressure member 92 is in the standby position separated externally from the substrate mounting region 311, the pressure member 92 does not interfere with the substrate S being loaded and unloaded, thereby allowing the substrate S to be loaded and unloaded smoothly. During implementation of the coating process, the pressure member 92 is separated from the substrate S so does not interfere with the slit nozzle 1, thereby allowing the coating process to be performed smoothly.

The temporary correction position means a position where pressure is applied from above to the peripheral part of the substrate S in the positioning position (see FIGS. 6B and 6C referred to later). Specifically, in the temporary correction position, a lower surface of the pressure member 92 covers the peripheral part of the substrate S from above and is located in the positioning position in the vertical direction Z (sign H2 in FIG. 6B). By doing so, even if the peripheral part of the substrate S in the positioning position has a shape warped upward, namely, even if the substrate S is warped into a recess shape, the pressure member 92 depresses the peripheral part of the substrate S from above in the temporary correction position to correct the warpage of the substrate S (temporary correcting process). As a result, even if the peripheral part of the substrate S is warped upward when the substrate S is loaded, the substrate S is subjected to the temporary correcting process in the positioning position to be supported by the plurality of lift pins 61 with the end surface Se of the substrate S facing a side surface of the alignment pin 82. Thus, it is possible to perform the positioning process stably.

In performing the positioning process, both the alignment pin 82 and the pressure member 92 abut on the substrate S. In this regard, in a configuration of the present embodiment, an abutment region where the alignment pin 82 abuts on the end surface Se of the substrate S and a pressure region where the pressure member 92 applies pressure to the peripheral part of the substrate S differ from each other in a peripheral direction of the substrate S, as shown in FIG. 2. As a result, it is possible to perform the temporary correcting process and the positioning process smoothly in the positioning position.

The final correction position means a position where the pressure member 92 applies pressure from above to the peripheral part of the substrate S mounted on the mounting surface 31 toward the mounting surface 31 (see FIG. 6E referred to later). Specifically, at the final correction position, the substrate S is sandwiched between the lower surface of the pressure member 92 and the mounting surface 31 to correct the warpage of the substrate S (final correcting process).

Each pressure member 92 is connected to a pressure drive part 93. When the pressure drive part 93 is actuated in response to a command from the controller 10, the pressure member 92 moves from the standby position, passes through the temporary correction position and the final correction position, and then returns to the standby position. A substrate holding motion including a sequence of such pressing and moving motions is conducted on each substrate S by causing the controller 10 to control each part of the substrate holding mechanism 200 as described next according to a program stored in advance.

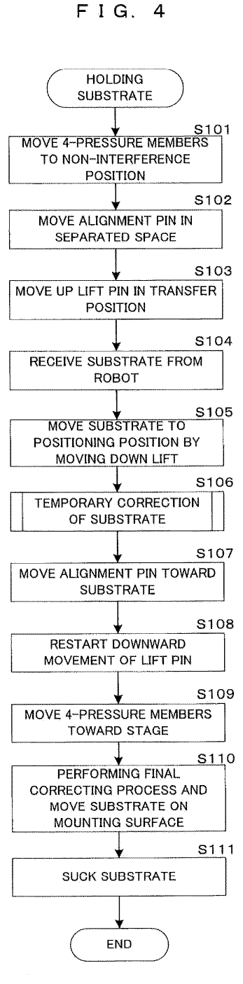

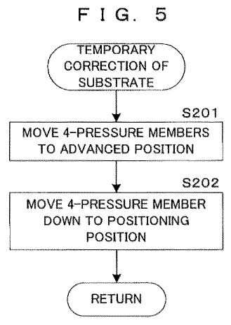

FIG. 4 is a flowchart showing an example of a substrate holding process performed by the substrate processing apparatus in FIG. 1. FIG. 5 is a flowchart showing a procedure of temporary correction on the substrate taken by the substrate holding mechanism in FIG. 2. FIGS. 6A and 6C to 6E are motion explanatory views showing motions conducted according to the flowchart in FIG. 4. FIG. 6B is a motion explanatory view showing a motion conducted according to the flowchart in FIG. 5.

In step S101, the pressure member 92 provided in response to each of the four sides of the mounting surface 31 moves to the standby position and is then put on standby. Specifically, as shown in FIG. 6A, the pressure member 92 moves to a non-interference position higher than the transfer position H1 and external to the substrate S being transported by a robot not shown in the drawings, and is then put on standby. As shown in FIG. 6A, in subsequent step S102, each alignment pin 82 is located in the separated space. The upper end of the lift pin 61 is housed in the pin housing hole 315. When the robot transports the substrate S to a position over the mounting surface 31, each lift pin 61 moves up from the pin housing hole 315 and the upper end of each lift pin 61 comes into point contact with the substrate S in the transfer position H1 (step S103), as represented as an arrow M1 in FIG. 6A. Then, the substrate S is received from the robot onto each lift pin 61 (step S104).

Next, as represented as an arrow M2 in FIG. 6B, the lift pin 61 moves down until the upper end of the lift pin 61 becomes located in the positioning position H2. By doing so, with the lower surface of the substrate S supported from below by the lift pin 61, the substrate S is moved to the positioning position H2 (step S105). Specifically, the central part of the substrate S is substantially aligned with the positioning position H2 in the vertical direction Z. On the other hand, the peripheral part of the substrate S is not always aligned with the positioning position H2. The reason for this is that, if the peripheral part of the loaded substrate S is warped upward, for example, the end surface Se of the substrate S becomes higher than the positioning position H2 in the vertical direction Z in some cases. Furthermore, a distance from the positioning position H2 is proportionate to a degree of the warpage of the substrate S. If a degree of the warpage of the substrate S becomes greater, the end surface Se of the substrate S may become higher than the upper end of the alignment pin 82. In this case, moving the alignment pin 82 horizontally toward the substrate causes the alignment pin 82 to abut directly on the lower surface of the substrate S, not on the end surface Se of the substrate S. This causes serious reduction in the accuracy of positioning the substrate in the horizontal direction.

Then, in the present embodiment, the temporary correcting process shown in FIG. 5 is performed on the substrate S (step S106). Specifically, as shown by arrows M3 in FIG. 6B, each of the four pressure members 92 moves horizontally to an advanced position to become located directly above a corresponding side of the substrate S (step S201). Next, as represented as an arrow M4 in FIG. 6B, each pressure member 92 moves down to the positioning position H2 (step S202). At this time, if the peripheral part of the substrate S is warped upward, the pressure member 92 moving down to the positioning position H2 applies pressure downward to the peripheral part of the substrate S with the warpage, thereby correcting the warpage of the substrate S to some extent. As a result, the peripheral part of the substrate S is located at a height substantially conforming to the positioning position H2 and lower than the upper end of the alignment pin 82. As a result, a side surface of the alignment pin 82 faces the end surface Se of the substrate S in the horizontal direction.

When the temporary correction on the substrate S is finished, each of the plurality of alignment pins 82 moves horizontally toward the substrate S in the positioning position H2 as represented as a sign M5 in FIG. 6C to locate the substrate S in a predetermined position in the horizontal direction (step S107: positioning process). As represented as a sign M6 in FIG. 6C, the alignment pin 82 moves farther from the substrate S after the positioning process to return to the initial retreat position. In this way, in the present embodiment, the substrate S is subjected to the positioning process while the substrate S is separated upward from the suction pad 71. As a result, the substrate S is located in the predetermined position in the horizontal direction relative to the mounting surface 31 while generation of dust from the suction pad 71 and wear of the suction pad 71 are prevented effectively.

Next, as represented as an arrow M7 in FIG. 6D, downward movement of the lift pin 61 is restarted (step S108). By doing so, the substrate S moves down toward the stage 3 while being supported by the lift pin 61. In synchronization with this movement, the pressure member 92 also moves down toward the stage 3 (step S109). Specifically, if the substrate S moving down is in a state after being subjected to the temporary correcting process in step S106, the substrate S moves down in this temporarily corrected state.

During the downward movement of the substrate S, the peripheral part of the substrate S abuts on the suction opening 711 of the suction pad 71 (see FIG. 6D). The lift pin 61 moves down further to house the upper end of the lift pin 61 into the pin housing hole 315, and the suction upper end portion of the suction pad 71 retreats into the recess. By doing so, the substrate S is mounted from the upper end of each lift pin 61 on the mounting surface 31 (step S110). Furthermore, the pressure member 92 applies pressure to the peripheral part of the substrate S against the mounting surface 31. By doing so, the shape of the substrate S is corrected so as to conform to the shape of the mounting surface 31. In this way, in the present embodiment, the substrate S is mounted on the mounting surface 31 while the final correcting process is performed. Next, the suction source 52 sucks air through an air hole, thereby sucking the substrate S on the mounting surface 31 (step S111). As a result, the substrate S is fixed to the mounting surface 31. Then, the pressure member 92 returns to the initial standby position. By doing so, the substrate holding process is finished. The coating process using the slit nozzle 1 is performed thereafter.

As described above, in the present embodiment, while the substrate S is supported from below by the plurality of lift pins 61 in the positioning position H2 separated upward from the suction pad 71, the alignment pin 82 abuts on the end surface Se of the substrate S. By doing so, the substrate S is aligned in a predetermined position in the horizontal direction relative to the mounting surface 31. During implementation of this positioning process (alignment process), the substrate S is separated from the suction pad 71 and is moved in a non-abutment state in the horizontal direction. After the positioning, the substrate S is mounted on the mounting surface 31 and is sucked under suction by the suction pad 71. Thus, while generation of dust from the suction pad 71 and wear of the suction pad 71 are prevented, it is possible to hold the substrate S under suction on the mounting table using the suction pad 71 with the substrate S located in the predetermined position relative to the mounting surface 31.

The temporary correcting process using the pressure unit 9 is performed in the positioning position H2 before implementation of the positioning process using the alignment pin 82. Thus, even if the loaded substrate S is warped upward at its peripheral part, the peripheral part of the substrate S is corrected to a height substantially equal to the positioning position H2 in the vertical direction Z, thereby allowing the alignment pin 82 to abut on the end surface Se of the substrate S reliably. Furthermore, in the present embodiment, the positioning process (alignment process) using the alignment pin 82 is performed while the pressure member 92 keeps making the temporary correction by applying pressure from above to the peripheral part of the substrate S. This allows the positioning process using the alignment pin 82 to be performed with high accuracy.

In the present embodiment, after positioning of the substrate S, the alignment pin 82 moves farther from the end surface Se of the substrate S and the lift pin 61 moves down to mount the substrate S on the mounting surface 31. At the same time, the peripheral part of the substrate S mounted on the mounting surface 31 is sandwiched between the mounting surface 31 and the pressure member 92 to correct the peripheral part of the substrate S (final correcting process). As a target of application of the processing liquid is the substrate S after being subjected to the final correcting process, it is possible to apply the processing liquid favorably to the surface Sa of the substrate S.

As described above, in the foregoing embodiment, the lift pin 61 corresponds to an example of a “support pin” of the present invention, and the alignment pin 82 corresponds to an example of a “positioning member” of the present invention.

The present invention is not limited to the foregoing embodiment but can be changed in various ways other than those described above without departing from the purport of the invention. As an example, in the above-described embodiment, a speed at which the substrate S moves down is determined freely. Meanwhile, the downward movement speed may be changed with reference to the pad abutment position H3. More specifically, with a speed of moving down from the positioning position H2 to the pad abutment position H3 and a speed of moving down from the pad abutment position H3 to the mounting surface defined as a “first downward movement speed” and a “second downward movement speed” respectively, the second downward movement speed may be set lower than the first downward movement speed. This is intended to cause expansion and contraction of the suction pad 71 to follow the downward movement of the substrate using the lift pin 61 without delay.

In the above-described embodiment, holding of the substrate S under suction is started after the substrate S is mounted on the mounting surface 31. However, timing of starting the suction is not limited to this. For example, start of the holding under suction may be timed to coincide with arrival of the moving-down substrate S at the pad abutment position H3.

In the above-described embodiment, the alignment pin 82 is used as the “positioning member” of the present invention. However, the shape of the “positioning member” is not limited to this but a block member having a columnar shape may be used as an example of the “positioning member,” for example.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

The present invention can be applied to a substrate holding device and method of holding substrates on mounting tables and a substrate processing apparatus technique of applying processing liquids to the substrates held on the mounting tables by supplying the processing liquids from slit nozzles.

What is claimed is:

1. A substrate holding device comprising:
a mounting table having a mounting surface on which a substrate is to be mounted;
an up-down unit configured to mount the substrate on the mounting surface by moving down a plurality of support pins supporting the substrate from below;
a suction unit configured to suck and hold a peripheral part of the substrate from below using a suction pad;
a positioning unit configured to position the substrate by abutting on an end surface of the substrate supported by the plurality of support pins at a positioning position separated upward from the suction pad; and
a controller configured to control the up-down unit, the suction unit, and the positioning unit so as to cause the up-down unit to mount the substrate on the mounting surface and to cause the suction unit to hold the substrate under suction while the substrate is positioned by the positioning unit.

2. The substrate holding device according to claim 1, comprising:
a pressure unit from which pressure is applicable from above to the peripheral part of the substrate supported by the plurality of support pins in the positioning position.

3. The substrate holding device according to claim 2, wherein
an abutment region where the positioning unit abuts on the end surface of the substrate and a pressure region where the pressure unit applies pressure to the peripheral part of the substrate differ from each other in a peripheral direction of the substrate.

4. The substrate holding device according to claim 3, wherein
the controller is configured to control the positioning unit and the pressure unit so as to cause the positioning unit to abut on the end surface of the substrate to position the substrate while causing the pressure unit to keep applying pressure to the peripheral part of the substrate.

5. The substrate holding device according to claim 4, wherein
the controller is configured to control the positioning unit and the up-down unit so as to cause the positioning unit to move farther from the end surface of the substrate after positioning of the substrate and to cause the up-down unit to move down the plurality of support pins to mount the substrate on the mounting surface.

6. The substrate holding device according to claim 5, wherein
the controller is configured to control the pressure unit so as to cause the pressure unit to move down together with downward movement of the plurality of support pins to sandwich the peripheral part of the substrate mounted on the mounting surface between the pressure unit and the mounting surface.

7. The substrate holding device according to claim 1, wherein
the suction pad has a suction upper end portion provided with a suction opening for sucking a lower surface of the substrate, and a suction lower end portion sunk in a recess provided in the mounting surface,
while the suction upper end portion is in a non-abutment state of not abutting on the lower surface of the substrate, the suction upper end portion protrudes to a pad abutment position higher than the mounting surface and lower than the positioning position, and while the suction upper end portion is in an abutment state of abutting on the lower surface of the substrate, the suction upper end portion retreats into the recess in conjunction with downward movement of the substrate to become sinkable in the recess at a moment when mounting of the substrate on the mounting surface is finished.

8. The substrate holding device according to claim 7, wherein
the controller is configured to control the up-down unit so as to move down the substrate from the positioning position to the pad abutment position at a first downward movement speed and to move down the substrate from the pad abutment position to the mounting surface at a second downward movement speed lower than the first downward movement speed.

9. A substrate processing apparatus comprising:
the substrate holding device according to claim 1; and
a slit nozzle configured to apply a processing liquid to a surface of the substrate by moving relative to the substrate in a horizontal direction while the substrate is mounted on the mounting surface and is held under suction on the mounting table by the suction pad.

10. A substrate holding method comprising:
(a) sucking and holding a substrate on a mounting surface of a mounting table using a suction pad of a suction unit;
(b) after the operation (a), positioning the substrate above the mounting surface and the suction pad by causing a positioning member to abut on an end surface of the substrate while supporting the substrate from below using a plurality of support pins; and
(c) after the operation (b), mounting the substrate on the mounting surface by moving down the plurality of support pins.
